(19) United States
(12) Patent Application Publication
(10) Pub. No.: US 2026/0023038 A1
(43) Pub. Date: Jan. 22, 2026

(54) Test Chamber and Control Method

(71) Applicant: Weiss Technik GmbH, Reiskirchen (DE)

(72) Inventor: Yannik Zahrt, Rabenau (DE)

(21) Appl. No.: 19/270,811

(22) Filed: Jul. 16, 2025

(30) Foreign Application Priority Data
Jul. 18, 2024 (EP) 24189407.0

(51) Int. Cl. G01N 25/48; G01N 25/50; H05K 7/20

(52) U.S. Cl. CPC G01N 25/4853; G01N 25/50; H05K 7/20354

(57) ABSTRACT

A method for conditioning air in a test space of a test chamber, the test space being sealable against an environment and being temperature-insulated, and a test chamber, in particular a climate chamber, for receiving test material. A temperature in a temperature range of −40° C. to +180° C. is established within the test space by a cooling device of a temperature control device of the test chamber, which comprises a cooling circuit with carbon dioxide as a refrigerant, a heat exchanger in the test space, a low-pressure compressor, and a high-pressure compressor downstream of the low-pressure compressor in a flow direction of the refrigerant, a gas cooler, and an expansion valve. The temperature in the test space is controlled and/or regulated by a control device of the test chamber, the cooling circuit having a valve device by which the refrigerant is conducted to the low-pressure compressor or to the high-pressure compressor.

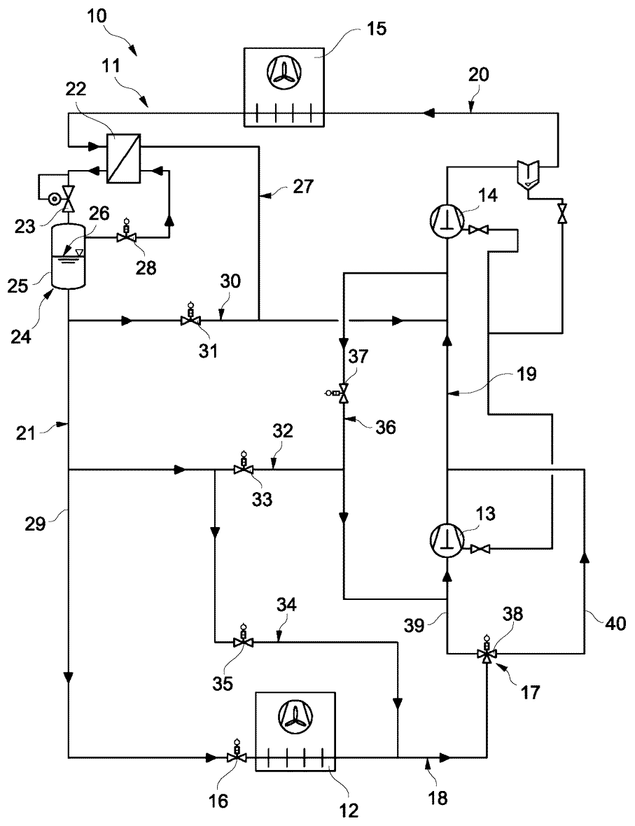

### CROSS-REFERENCE TO RELATED APPLICATIONS

This patent application claims priority to European Patent Application No. 24189407.0 filed Jul. 18, 2024, the contents of which are incorporated herein by reference in its entirety for all purposes.

### TECHNICAL FIELD

This disclosure relates to a test chamber, in particular a climate chamber, for conditioning air and to a method for conditioning air in a test space of a test chamber, in particular a climate chamber, for receiving test material, the test space being sealable against an environment and being temperature-insulated, a temperature in a temperature range of −40° C. to +180° C. being established within the test space by a cooling device of a temperature control device of the test chamber, which comprises a cooling circuit with carbon dioxide as a refrigerant, a heat exchanger in the test space, a low-pressure compressor, and a high-pressure compressor downstream of the low-pressure compressor in a flow direction of the refrigerant, a gas cooler, and an expansion valve, the temperature in the test space being controlled and/or regulated by a control device of the test chamber.

### BACKGROUND

Test chambers of this kind are regularly used to test physical and/or chemical properties of objects, in particular devices. For example, there are known temperature test cabinets or climatic test cabinets within which temperatures in a range from −70° C. to +180° C. can be set. In the case of climatic test cabinets, desired climatic conditions can be additionally set, to which the device or the test material is then exposed over a defined period of time. The temperature of a test space containing the test material to be tested is regularly controlled in an air circulation duct within the test space. The air circulation duct forms an air treatment space in the test space, in which heat exchangers for heating or cooling the air flowing through the air circulation duct or the test space are disposed. A fan or a ventilator aspirates the air in the test space and guides it through the air circulation duct to the respective heat exchangers. The test material can thus be temperature-controlled or also exposed to a defined change in temperature. In this case, during a test interval, a temperature can change, for example, between a temperature maximum and a temperature minimum of the test chamber. A test chamber of this kind is known from EP 0 344 397 A2, for example.

The refrigerant used in a cooling circuit should have a relatively low CO₂ equivalent, i.e., a relative greenhouse potential or global warming potential (GWP) should be as low as possible in order to avoid indirect damage to the environment by the refrigerant upon release. It is therefore also known for carbon dioxide (CO₂) to be used as a pure-substance refrigerant. Carbon dioxide is available at low cost, is non-flammable and is essentially environmentally neutral with a GWP of 1. Carbon dioxide has a freezing temperature or a triple point of −56.6° C., which makes it impossible to achieve lower temperatures with carbon dioxide alone.

Since carbon dioxide as a refrigerant has a very high volumetric cooling capacity, a very high cooling capacity is provided by the cooling circuit even when using compressors with a very low stroke volume flow. In addition, a pressure range of cooling circuits with carbon dioxide as the refrigerant is very high (up to 120 bar) in transcritical operation, which is why the components required to form the cooling circuit are comparatively expensive.

Furthermore, cooling devices are known which are configured as what is referred to as booster systems. In a cooling circuit of said cooling devices, a high-pressure compressor is always connected in series downstream of a low-pressure compressor, so that the refrigerant is compressed in stages with the low-pressure compressor and then with the high-pressure compressor. Due to the high demands on temperature control within the temperature range of the test space, a load requirement frequently fluctuates during operation of the test chamber. Hence, a cooling capacity generated by the compressors and the expansion valve has to be infinitely variable. At the same time, it is desirable for the compressors to not be switched on and off frequently in order to extend a service life of the compressors.

In order to be able to face load fluctuations, which occur in the test space as a result of a temperature change, during operation, it is also known to operate cooling devices with two circuits. In this case, an expansion valve is assigned to each cooling circuit and different refrigerants are used in the respective cooling circuits, for example, in order to be able to cover different temperature ranges. The two cooling circuits flow through the heat exchanger used in this case within the test space, which, however, results in a part of a surface area of the heat exchanger being available for the respective cooling circuits. Therefore, larger temperature differences have to be established at the heat exchanger, which, however, also requires a higher capacity of the cooling device and/or the respective compressors. When using carbon dioxide as a refrigerant, it is then disadvantageous that an evaporation temperature cannot be lowered below −56.6° C.

### SUMMARY

Hence, the object of the present disclosure is to propose a method for conditioning air in a test space of a test chamber and a test chamber which enable an energy-efficient operation.

This object is attained by a method having the features described herein and a test chamber having the features described herein.

In the method according to the disclosure for conditioning air in a test space of a test chamber, in particular a climate chamber, for receiving test material, the test space being sealable against an environment and being temperature-insulated, a temperature in a temperature range of −40° C. to +180° C. is established within the test space by a cooling device of a temperature control device of the test chamber, which comprises a cooling circuit with carbon dioxide as a refrigerant, a heat exchanger in the test space, a low-pressure compressor, and a high-pressure compressor downstream of the low-pressure compressor in a flow direction of the refrigerant, a gas cooler, and an expansion valve, the temperature in the test space being controlled and/or regulated by a control device of the test chamber, wherein the cooling circuit has a valve device by which the refrigerant is conducted to the low-pressure compressor or to the high-pressure compressor.

Since the high-pressure compressor is disposed downstream of the low-pressure compressor in the flow direction of the refrigerant, the refrigerant can either be fed to the low-pressure compressor and then to the high-pressure compressor or to the high-pressure compressor alone by the valve device. Since at least one heat exchanger alone, through which the refrigerant of the cooling circuit flows, is disposed in the test space, the use of the entire surface area of the heat exchanger with the cooling circuit for controlling the temperature of the test space is made possible. Depending on the load requirement, the low-pressure compressor together with the high-pressure compressor or just the high-pressure compressor alone can then be operated. Since the entire heat exchanger or its entire effective surface area is usable for controlling the temperature of the test space irrespective of an operation of the compressors, a comparatively small temperature difference between the heat exchanger and a test space atmosphere is required compared to a heat exchanger which is only partially used. In this case, a compressor capacity can also be lower and the test chamber can be operated with carbon dioxide as a refrigerant with more dynamic temperature changes. Depending on the temperature requirement in the test chamber, the control device can control and/or regulate the valve device. If, for example, a temperature of −20° C. is to be established at the heat exchanger, refrigerant is fed to the high-pressure compressor alone via the valve device. If a temperature of, for example, −50° C. is to be established at the heat exchanger, the refrigerant is fed to the low-pressure compressor via the valve device and then to the high-pressure compressor. Therefore, during ongoing operation of the test chamber, the low-pressure compressor can be switched off temporarily, thereby saving a large part of the energy otherwise required for the operation of the compressors.

The valve device may be disposed downstream of the heat exchanger in a flow direction of the refrigerant in the cooling circuit, wherein refrigerant can be conducted to the low-pressure compressor or, by bypassing the low-pressure compressor, to the high-pressure compressor by the valve device. The valve device can be realized by one or more valves, for example magnetic valves. It is essential that the valve device can conduct refrigerant directly to the low-pressure compressor or past the low-pressure compressor directly to the high-pressure compressor depending on a temperature requirement of the control device. When refrigerant is conducted to the high-pressure compressor by bypassing the low-pressure compressor, the low-pressure compressor can be switched off.

The cooling circuit may have a compressor bypass which may be connected downstream of the heat exchanger and upstream of the low-pressure compressor and to an intermediate-pressure side of the cooling circuit downstream of the low-pressure compressor and upstream of the high-pressure compressor in a flow direction of the refrigerant, wherein refrigerant can be conducted to the low-pressure compressor or, via the compressor bypass, to the high-pressure compressor by the valve device. The compressor bypass may be realized by a line section of the cooling circuit, which bridges the low-pressure compressor.

Depending on a target temperature, the control device may operate the high-pressure compressor and switch off the low-pressure compressor and actuate the valve device in such a manner that refrigerant is conducted to the high-pressure compressor, or operate the high-pressure compressor and the low-pressure compressor and actuate the valve device in such a manner that refrigerant is conducted to the low-pressure compressor. Downstream of the low-pressure compressor, the refrigerant can then be conducted to the high-pressure compressor. In all cases, the cooling circuit may be transcritically operated without a complete liquefaction of the refrigerant taking place in the cooling circuit.

A low-pressure bypass having at least one low-pressure valve may be realized in the cooling circuit, wherein the low-pressure bypass may be connected to a medium-pressure side of the cooling circuit downstream of the gas cooler and upstream of the expansion valve and to a low-pressure side of the cooling circuit downstream of the valve device and upstream of the low-pressure compressor, a suction-gas temperature and/or a suction-gas pressure of the refrigerant on the low-pressure side of the cooling circuit upstream of the low-pressure compressor may be regulated in such a manner that refrigerant can be metered into the low-pressure side via the low-pressure valve. Optionally, the low-pressure bypass may be connected to the medium-pressure side downstream of the gas cooler and downstream of an internal heat exchanger in the cooling circuit. Thus, the low-pressure valve can be used to influence the suction-gas temperature and/or the suction-gas pressure upstream of the low-pressure compressor in such a manner that a final compression temperature of the low-pressure compressor is within an operating range intended for the low-pressure compressor. For example, a suction-gas temperature of the low-pressure compressor can rise particularly sharply if a temperature in the test space is to be reduced from, for example, +180° C. to a lower temperature. Since the heat exchanger is located in the test space, the refrigerant, at particularly high temperatures in the test space of +180° C., for example, can flow from the heat exchanger to the low-pressure compressor at this temperature. Before the heavily overheated refrigerant is fed to the low-pressure compressor, it can be cooled by the refrigerant expanded via the low-pressure valve. The low-pressure bypass is usable even if a sufficiently large mass flow has to be formed upstream of the low-pressure compressor for a compressor operation.

A regulating bypass having at least one regulating valve may be realized in the cooling circuit, wherein the regulating bypass may be connected to an intermediate-pressure side of the cooling circuit downstream of the low-pressure compressor and upstream of the high-pressure compressor and to a low-pressure side of the cooling circuit upstream of the low-pressure compressor and downstream of the valve device, wherein refrigerant may be metered into the low-pressure side via the regulating valve, wherein a suction-gas temperature and/or a suction-gas pressure of the refrigerant on the low-pressure side of the cooling circuit upstream of the low-pressure compressor may be regulated and/or a difference in pressure between the intermediate-pressure side and the low-pressure side of the cooling circuit may be equalized. For example, the low-pressure compressor may be operated together with the high-pressure compressor in a temperature range of ≤−10° C., wherein the regulating valve can, in this case, first be closed completely. The regulating valve can be used for a capacity control of the low-pressure compressor by conducting cold, gaseous refrigerant from the intermediate-pressure side back to the low-pressure side. In this case, an injection of liquid refrigerant into the low-pressure side, for example via a low-pressure bypass, can be dispensed with. Furthermore, a suction pressure upstream of the low-pressure compressor can be set by the control device by the regulating bypass in such a manner that the refrigerant upstream of the low-pressure compressor is in a state below the triple point of carbon dioxide. By dispensing with an injection of liquid refrigerant into the low-pressure side and the feeding of cold, gaseous refrigerant from the intermediate-pressure side, a suction pressure upstream of the low-pressure compressor can be lowered below the triple point without dry ice formation occurring. This is particularly advantageous in the case of long suction lines in order to compensate for pressure loss via the suction line and in order to ensure that a sufficiently high difference between the temperature in the test space and a temperature at the heat exchanger and/or an evaporation temperature of the refrigerant exists in the case of low temperatures in the test space.

The cooling circuit may have an intermediate-pressure bypass which may be connected to a medium-pressure side of the cooling circuit downstream of the gas cooler and upstream of the expansion valve and to an intermediate-pressure side of the cooling circuit upstream of the high-pressure compressor and downstream of the low-pressure compressor, wherein refrigerant may be metered from the medium-pressure side into the intermediate-pressure side by an intermediate-pressure valve. In this case, a so-called intermediate-pressure injection of refrigerant into a line and/or intermediate-pressure side connecting the low-pressure compressor to the high-pressure compressor can be carried out with the intermediate-pressure bypass. The refrigerant conducted via the intermediate-pressure bypass can, in this case, be added to the refrigerant circulating in the cooling circuit at this point. By adding the refrigerant, the temperature of the refrigerant, which is upstream of the high-pressure compressor, can be controlled. Optionally, the intermediate-pressure bypass may be connected to the medium-pressure side downstream of the gas cooler and downstream of an internal heat exchanger in the cooling circuit. Thus, the intermediate-pressure valve can be used to influence the suction-gas temperature and/or the suction-gas pressure upstream of the high-pressure compressor in such a manner that a final compression temperature of the high-pressure compressor is within an operating range intended for the high-pressure compressor. Thus, a suction-gas temperature of the high-pressure compressor can rise particularly sharply if a temperature in the test space is to be reduced from, for example, +180° C. to a lower temperature. Since the heat exchanger is located in the test space, the refrigerant, at particularly high temperatures in the test space of +180° C., for example, can flow from the heat exchanger to the high-pressure compressor at this temperature. Before the heavily overheated refrigerant is fed to the high-pressure compressor, it can be cooled by the refrigerant expanded via the intermediate-pressure valve. The intermediate-pressure bypass is usable even if a sufficiently large mass flow has to be formed upstream of the high-pressure compressor for a compressor operation.

The cooling circuit may have a high-pressure valve and a storage device which may be connected to a high-pressure side of the cooling circuit downstream of the gas cooler and upstream of the expansion valve, wherein refrigerant may be metered into the storage device via the high-pressure valve. A first expansion of the refrigerant can be carried out by the high-pressure valve, wherein said refrigerant can then be introduced into the storage device directly downstream of the high-pressure valve. Thus, the storage device is installed on the medium-pressure side of the cooling circuit downstream of the high-pressure valve. Within the storage device, which can be realized by a pressure vessel, a phase separation of the refrigerant can then take place to the effect that liquid refrigerant collects in a lower area of the storage device and gaseous refrigerant in an upper area of the storage device. The liquid refrigerant and the gaseous refrigerant can then be used for the operation of the cooling circuit depending on a temperature requirement. The liquid refrigerant can be used via the expansion valve for the normal cooling of the heat exchanger. The gaseous refrigerant can be conducted to the high-pressure compressor, for example. This is in particular advantageous if liquid refrigerant accumulates upstream of the high-pressure compressor, which is to be avoided.

The cooling circuit may have an internal heat exchanger which may be connected to the high-pressure side of the cooling circuit downstream of the gas cooler and upstream of the expansion valve, wherein the internal heat exchanger may be coupled to a flash-gas bypass of the cooling circuit, wherein the flash-gas bypass may be connected to the storage device downstream of the internal heat exchanger and upstream of the expansion valve and to an intermediate-pressure side of the cooling circuit upstream of the high-pressure compressor and downstream of the low-pressure compressor, wherein gaseous refrigerant may be metered from the storage device via the internal heat exchanger into the intermediate-pressure side by a flash-gas valve of the flash-gas bypass. The flash-gas bypass is consequently connected in an upper area of the storage device to said storage device in such manner that gaseous refrigerant can be taken out of the storage device. In this case, the flash-gas valve can serve to discharge and meter gaseous refrigerant from the storage device. Transcritical refrigerant flowing from the gas cooler to the high-pressure valve can be subcooled by the internal heat exchanger. At the same time, gaseous refrigerant can be overheated in the flash-gas bypass by the internal heat exchanger and be conducted to the high-pressure compressor. This is particularly advantageous since no liquid refrigerant should accumulate upstream of the high-pressure compressor. Thus, it can be ensured with the overheated refrigerant from the flash-gas bypass that solely gaseous refrigerant is aspirated by the high-pressure compressor.

Another bypass having at least one other valve may be realized in the cooling circuit, wherein the other bypass may be connected to a medium-pressure side of the cooling circuit downstream of the gas cooler and upstream of the expansion valve and to a low-pressure side of the cooling circuit downstream of the heat exchanger and upstream of the valve device, wherein a suction-gas temperature and/or a suction-gas pressure of the refrigerant on the low-pressure side of the cooling circuit upstream of the valve device may be regulated in such a manner that refrigerant may be metered into the low-pressure side via the other valve. The other bypass can in particular be used to cool the valve device if a temperature for the valve device is too high in this area. Refrigerant can also be conducted upstream of the low-pressure compressor via the other bypass in order to provide a required mass flow upstream of the low-pressure compressor. The other valve can also be used to influence a suction-gas temperature and/or the suction-gas pressure upstream of the low-pressure compressor, and, depending on the actuation of the valve device, upstream of the high-pressure device, in such a manner that a final compression temperature of the low-pressure compressor and the high-pressure compressor, respectively, is within an operating range intended for the low-pressure compressor and the high-pressure compressor, respectively.

Advantageously, pure carbon dioxide may be used as the refrigerant. Pure carbon dioxide has a GWP of 1, is non-flammable, non-hazardous and available at low cost. In addition, carbon dioxide is a pure substance or azeotropic, which is what makes the advantageous implementation of the method and its variations possible in the first place. A refrigerant with zeotropic behavior, on the other hand, would hardly make it possible to provide a sufficient quantity of gaseous refrigerant at a very low difference in temperature and thus hardly allow for capacity control of the respective compressors.

A temperature in a temperature range of −50° C. to +180° C., preferably −55° C. to +180° C., can be established within the test space by the temperature control device.

A rotation speed of the high-pressure compressor and/or of the low-pressure compressor can be controlled. The high-pressure compressor and/or the low-pressure compressor can each be realized with a frequency converter which allows for a rotation speed control of the compressors. By reducing the rotation speed, a mass flow of the refrigerant can be further reduced in a partial-load operating state of the cooling circuit and, thus, an efficiency of the cooling device in this operating state can be further increased. Furthermore, a rotation speed control of the low-pressure compressor allows a raising and lowering of the rotation speed of the low-pressure compressor by the control device in such a manner that a suction-gas pressure on a low-pressure side of the cooling circuit can be changed and can thus be adjusted in a desired manner.

The test chamber according to the disclosure, in particular climate chamber, for conditioning air, comprises a test space for receiving test material, the test space being sealable against an environment and being temperature-insulated, and a temperature control device for controlling the temperature of the test space, a temperature in a temperature range of −40° C. to +180° C. being establishable within the test space by the temperature control device, the temperature control device having a cooling device comprising a cooling circuit with carbon dioxide as a refrigerant, a heat exchanger in the test space, a low-pressure compressor, and a high-pressure compressor downstream of the low-pressure compressor in a flow direction of the refrigerant, a gas cooler, and an expansion valve, the test chamber having a control device for controlling and/or regulating the temperature in the test space, wherein the cooling circuit has a valve device by which the refrigerant is capable of being conducted to the low-pressure compressor or to the high-pressure compressor. Regarding the advantages of the test chamber according to the disclosure, reference is made to the description of advantages of the method according to the disclosure.

The valve device may be realized by a 3-way valve. In principle, it is possible to realize the valve device with a plurality of valves which themselves are actuated by the control device in such a manner that refrigerant is conducted to the low-pressure compressor or the high-pressure compressor. However, the 3-way valve allows for a particularly simple realization of the valve device and a selective feeding of refrigerant to the low-pressure compressor or the high-pressure compressor. The 3-way valve can be connected to a cooling circuit downstream of the heat exchanger and upstream of the low-pressure compressor and, via a compressor bypass, upstream of the high-pressure compressor and downstream of the low-pressure compressor. The 3-way valve can be easily actuated by the control device.

The heat exchanger may be realized with only one exchanger body, wherein only one line of the cooling circuit may run through the exchanger body. Thus, in this case, it is also possible to fully use a surface area of the exchanger body, which is effective for controlling the temperature, with the line of the cooling circuit such that a dynamic change of the temperature in the test space can occur even with a comparatively small temperature difference of the exchanger body and the temperature in the test space. It is essential that the exchanger body be connected to the cooling circuit directly downstream of the expansion valve in such a manner that only refrigerant flowing via the expansion valve is conducted through the exchanger body. In this context, an exchanger body is understood to be a body that can be composed of one or more parts, for example, and through which the refrigerant flows. This also includes line arrangements that are provided with fins for better heat transfer. In this case, the fins form the exchanger body together with the line arrangement(s). In this case, the exchanger body has a surface area effective for heat transfer.

The temperature control device may comprise a heating device having a heater and a heating heat exchanger in the test space. For example, the heating device can be an electrical resistance heater that heats the heating heat exchanger in such a manner that an increase in temperature in the test space is made possible via the heating heat exchanger. If the heat exchanger and the heating heat exchanger can be controlled and/or regulated in a targeted manner by the control device to cool or heat the air circulated in the test space, a temperature in the temperature range specified above can then be established within the test space by the temperature control device.

Other embodiments of a test chamber are apparent from the descriptions of features of the dependent claims.

### BRIEF DESCRIPTION OF THE FIGURE

Hereinafter, a preferred embodiment of the disclosure is explained in more detail with reference to the accompanying drawing.

The FIGURE shows an embodiment of a cooling device of a test chamber.

### DETAILED DESCRIPTION

The Figure shows a possible embodiment of a cooling device 10 of a test chamber (not illustrated in the case at hand). Cooling device 10 comprises a cooling circuit 11 with carbon dioxide (CO₂) as a refrigerant, a heat exchanger 12, a low-pressure compressor 13, a high-pressure compressor 14, a gas cooler 15, an expansion valve 16, and a valve device 17. In the case at hand, gas cooler 15 is configured in the manner of a heat exchanger and is cooled by a heat transfer medium, such as air or water. Heat exchanger 12 is disposed in an air treatment duct (not illustrated in the case at hand) of the test chamber in such a manner that a fan (not illustrated in the case at hand) can circulate the air in the test space at heat exchanger 12. Furthermore, cooling circuit 11 has a low-pressure side 18, an intermediate-pressure side 19, a high-pressure side 20 and a medium-pressure side 21. In low-pressure side 18, a pressure of the refrigerant is comparatively lower than in intermediate-pressure side 19. In intermediate-pressure side 19, a pressure of the refrigerant is comparatively lower than in medium-pressure side 21 and, in medium-pressure side 21, a pressure of the refrigerant is comparatively lower than in high-pressure side 20.

Downstream of gas cooler 15 in a flow direction of the refrigerant, cooling circuit 11 further has an internal heat exchanger 22 and a high-pressure valve 23 via which gaseous refrigerant is expanded and/or metered into a storage device 24. Storage device 24 is realized as a pressure vessel 25 in which a phase boundary 26 forms between the liquid and the gaseous refrigerant. A flash-gas bypass 27 having a flash-gas valve 28 of cooling circuit 11 is connected to storage device 24 in such a manner that gaseous refrigerant can be taken out of storage device 24 and conducted to intermediate-pressure side 19 downstream of low-pressure compressor 13 and upstream of high-pressure compressor 14 in a flow direction of the refrigerant. Furthermore, a line section 29 is connected to storage device 24 in such a manner that liquid refrigerant can be taken out of storage device 24 and conducted to expansion valve 16.

Refrigerant flowing from gas cooler 15 to high-pressure valve 23 can be subcooled by internal heat exchanger 22, wherein the refrigerant flowing into intermediate-pressure side 19 upstream of high-pressure compressor 14 via flash-gas valve 28 can be overheated in internal heat exchanger 22. This ensures that gaseous refrigerant is located upstream of high-pressure compressor 14 such that high-pressure compressor 14 can aspirate only this refrigerant.

In addition, cooling circuit 11 comprises an intermediate-pressure bypass 30 having an intermediate-pressure valve 31, wherein intermediate-pressure bypass 30 is connected to line section 29 downstream of storage device 24 and to cooling circuit 11 and/or intermediate-pressure side 19 downstream of low-pressure compressor 13 and upstream of high-pressure compressor 14. Liquid refrigerant can be metered from storage device 24 into intermediate-pressure side 19 by intermediate-pressure valve 31, for example, if a temperature of the refrigerant is to be lowered upstream of high-pressure compressor 14. Furthermore, cooling circuit 11 comprises a low-pressure bypass 32 having a low-pressure valve 33, low-pressure bypass 32 being connected to line section 29 downstream of storage device 24 and to low-pressure side 18 directly upstream of low-pressure compressor 13 and downstream of valve device 17. Liquid refrigerant can be metered from storage device 24 into low-pressure side 18 upstream of low-pressure compressor 13 by low-pressure valve 33, for example, if refrigerant aspirated by low-pressure compressor 13 is to be cooled.

Cooling circuit 11 has another bypass 34 having another valve 35. Other bypass 34 is connected to line section 29 downstream of storage medium 24 and to low-pressure side 18 of cooling circuit 11 downstream of heat exchanger 12 and upstream of valve device 17. Liquid refrigerant can be metered from storage device 24 into low-pressure side 18 upstream of valve device 17 by other valve 35. This makes it possible to cool valve device 17, if necessary, and to provide a sufficient mass flow for low-pressure compressor 13 or high-pressure compressor 14.

Furthermore, cooling circuit 11 has a regulating bypass 36 having a regulating valve 37. Regulating bypass 36 is connected to intermediate-pressure side 19 downstream of low-pressure compressor 13 and upstream of high-pressure compressor 14 and to low-pressure side 18 of cooling circuit 11 upstream of low-pressure compressor 13 and downstream of valve device 17. Refrigerant can be metered from intermediate-pressure side 19 into low-pressure side 18 via regulating valve 37. This makes it possible to regulate a suction-gas temperature and/or a suction-gas pressure of the refrigerant on low-pressure side 18 upstream of low-pressure compressor 13 and to equalize, if required, a difference in pressure between intermediate-pressure side 19 and low-pressure side 18 of cooling circuit 11.

Valve device 17 is realized by a 3-way valve 38. Depending on the temperature requirement of a control device (not illustrated) of the test chamber, 3-way valve 38 is actuated by the control device in such a manner that refrigerant flowing from heat exchanger 12 is conducted directly to low-pressure compressor 13 via a low-pressure line 39 directly connected to 3-way valve 38. This refrigerant is compressed by low-pressure compressor 13 and then passes on to high-pressure compressor 14 for further compression. The control device can also actuate 3-way valve 38 in such a manner that the refrigerant reaches high-pressure compressor 14 by bypassing low-pressure compressor 13 via a compressor bypass 40 directly connected to 3-way valve 38. Compressor bypass 40 is connected to intermediate-pressure side 19 downstream of low-pressure compressor 13 and upstream of high-pressure compressor 14. Depending on a temperature requirement, it is thus possible to operate low-pressure compressor 13 together with high-pressure compressor 14 or just high-pressure compressor 14 alone. Since, in this case, low-pressure compressor 13 is switched off, significant energy saving can be achieved. High-pressure compressor 14 is operated alone in particular if, for example, a temperature of −20° C. is to be established in the test space. Low-pressure compressor 13 and high-pressure compressor 14 are operated together if, for example, a temperature of −50° C. is to be established in the test space.

Heat exchanger 12 is preferably realized with only one exchanger body (not illustrated in the case at hand), only one line of cooling circuit 11 running through the exchanger body. Thus, a surface area of the exchanger body can be fully used with cooling circuit 11, which is why a temperature difference between an atmosphere of the test space and heat exchanger 12 can be comparatively small if a temperature change is to be established in the test space. Furthermore, a heating device (not illustrated in the case at hand) having a heater and a heating heat exchanger is provided in the test space.

1. A method for conditioning air in a test space of a test chamber, in particular a climate chamber, for receiving test material, the test space being sealable against an environment and being temperature-insulated, a temperature in a temperature range of −40° C. to +180° C. being established within the test space by a cooling device of a temperature control device of the test chamber, which comprises a cooling circuit with carbon dioxide (CO₂) as a refrigerant, a heat exchanger in the test space, a low-pressure compressor, and a high-pressure compressor downstream of the low-pressure compressor in a flow direction of the refrigerant, a gas cooler, and an expansion valve, the temperature in the test space being controlled and/or regulated by a control device of the test chamber,
wherein
the cooling circuit has a valve device by which the refrigerant is conducted to the low-pressure compressor or to the high-pressure compressor.

2. The method according to claim 1,
wherein
the valve device is disposed downstream of the heat exchanger in a flow direction of the refrigerant in the cooling circuit, refrigerant being conducted to the low-pressure compressor or, by bypassing the low-pressure compressor, to the high-pressure compressor by the valve device.

3. The method according to claim 1,
wherein
the cooling circuit has a compressor bypass which is connected downstream of the heat exchanger and upstream of the low-pressure compressor and to an intermediate-pressure side of the cooling circuit downstream of the low-pressure compressor and upstream of the high-pressure compressor in a flow direction of the refrigerant, refrigerant being conducted to the low-pressure compressor or, via the compressor bypass, to the high-pressure compressor by the valve device.

4. The method according to claim 1,
wherein
depending on a target temperature, the control device operates the high-pressure compressor and switches the low-pressure compressor off and actuates the valve device in such a manner that refrigerant is conducted to the high-pressure compressor, or operates the high-pressure compressor and the low-pressure compressor and actuates the valve device in such a manner that refrigerant is conducted to the low-pressure compressor.

5. The method according to claim 1,
wherein
a low-pressure bypass having at least one low-pressure valve is realized in the cooling circuit, the low-pressure bypass being connected to a medium-pressure side of the cooling circuit downstream of the gas cooler and upstream of the expansion valve and to a low-pressure side of the cooling circuit downstream of the valve device and upstream of the low-pressure compressor, a suction-gas temperature and/or a suction-gas pressure of the refrigerant on the low-pressure side of the cooling circuit upstream of the low-pressure compressor being regulated in such a manner that refrigerant is metered into the low-pressure side via the low-pressure valve.

6. The method according to claim 1,
wherein
a regulating bypass having at least one regulating valve is realized in the cooling circuit, the regulating bypass being connected to an intermediate-pressure side of the cooling circuit downstream of the low-pressure compressor and upstream of the high-pressure compressor and to a low-pressure side of the cooling circuit upstream of the low-pressure compressor and downstream of the valve device, refrigerant being metered into the low-pressure side via the regulating valve, a suction-gas temperature and/or a suction-gas pressure of the refrigerant on the low-pressure side of the cooling circuit upstream of the low-pressure compressor being regulated and/or a difference in pressure between the intermediate-pressure side and the low-pressure side of the cooling circuit being equalized.

7. The method according to claim 1,
wherein
the cooling circuit has an intermediate-pressure bypass connected to a medium-pressure side of the cooling circuit downstream of the gas cooler and upstream of the expansion valve and to an intermediate-pressure side of the cooling circuit upstream of the high-pressure compressor and downstream of the low-pressure compressor, refrigerant being metered from the medium-pressure side into the intermediate-pressure side by an intermediate-pressure valve.

8. The method according to claim 1,
wherein
the cooling circuit has a high-pressure valve and a storage device which are connected to a high-pressure side of the cooling circuit downstream of the gas cooler and upstream of the expansion valve, refrigerant being metered into the storage device via the high-pressure valve.

9. The method according to claim 8,
wherein
the cooling circuit has an internal heat exchanger connected to the high-pressure side of the cooling circuit downstream of the gas cooler and upstream of the expansion valve, the internal heat exchanger being coupled to a flash-gas bypass of the cooling circuit, the flash-gas bypass being connected to the storage device downstream of the internal heat exchanger and upstream of the expansion valve and to an intermediate-pressure side of the cooling circuit upstream of the high-pressure compressor and downstream of the low-pressure compressor, gaseous refrigerant being metered from the storage device via the internal heat exchanger into the intermediate-pressure side by a flash-gas valve.

10. The method according to claim 1,
wherein
another bypass having at least one other valve being realized in the cooling circuit, the other bypass being connected to a medium-pressure side of the cooling circuit downstream of the gas cooler and upstream of the expansion valve and to a low-pressure side of the cooling circuit downstream of the heat exchanger and upstream of the valve device, a suction-gas temperature and/or a suction-gas pressure of the refrigerant on the low-pressure side of the cooling circuit upstream of the valve device being regulated in such a manner that refrigerant is metered into the low-pressure side via the other valve.

11. The method according to claim 1,
wherein
pure carbon dioxide (CO₂) is used as the refrigerant.

12. A test chamber, in particular a climate chamber, for conditioning air, the test chamber comprising a test space for receiving test material, the test space being sealable against an environment and being temperature-insulated, and a temperature control device for controlling the temperature of the test space, a temperature in a temperature range of −40° C. to +180° C. being establishable within the test space by means of the temperature control device, the temperature control device having a cooling device comprising a cooling circuit (11) with carbon dioxide as a refrigerant, a heat exchanger in the test space, a low-pressure compressor, and a high-pressure compressor downstream of the low-pressure compressor in a flow direction of the refrigerant, a gas cooler, and an expansion valve, the test chamber having a control device for controlling and/or regulating the temperature in the test space,
wherein
the cooling circuit has a valve device by which the refrigerant is capable of being conducted to the low-pressure compressor or to the high-pressure compressor

13. The test chamber according to claim 12,
wherein
the valve device is realized by a 3-way valve.

14. The test chamber according to claim 12,
wherein
the heat exchanger is realized with only one exchanger body, only one line of the cooling circuit running through the exchanger body.

15. The test chamber according to claim 12,
wherein
the temperature control device comprises a heating device having a heater and a heating heat exchanger in the test space.
